(19) United States
(12) Patent Application Publication
(10) Pub. No.: US 2013/0291933 A1
(43) Pub. Date: Nov. 7, 2013

(54) SiOx n-LAYER FOR MICROCRYSTALLINE PIN JUNCTION

(71) Applicants: Markus Kupich, Buchs (CH); Daniel Lepori, Castagnola (CH)

(72) Inventors: Markus Kupich, Buchs (CH); Daniel Lepori, Castagnola (CH)

(73) Assignee: TEL SOLAR AG, Trubbach (CH)

(21) Appl. No.: 13/976,695

(22) PCT Filed: Dec. 23, 2011
(86) PCT No.: PCT/EP2011/074002

§ 371 Date: Jun. 27, 2013

Related U.S. Application Data
(60) Provisional application No. 61/427,865, filed on Dec. 29, 2010.

(51) Int. Cl. H01L 31/076; H01L 31/18

(52) U.S. Cl. CPC H01L 31/076; H01L 31/182
USPC 136/255; 438/87

(57) ABSTRACT

The present invention concerns a light conversion device comprising at least direction of impinging light one photovoltaic light conversion layer stack (43, 51) comprising a p-i-n junction and situated between a front (42) and back (47) electrode, wherein the n-layer (49) of the layer stack (43) situated closest to the back electrode (47) consists of a n-doped silicon- and oxygen-containing (SiOx) microcrystalline layer, and is in direct contact with the back electrode (47). The invention equally concerns a corresponding method for manufacturing such a light conversion device. The requirement for intermediate adhesion/interface layers between SiOx layer and back electrode can thus be obviated, resulting in simplified manufacture.

### FIELD OF THE INVENTION

Photovoltaic solar energy conversion offers the perspective to provide for an environmentally friendly means to generate electricity. Therefore, the development of more cost-effective means of producing photovoltaic energy conversion units attracted attention in the recent years. Amongst different approaches for producing low-cost solar cells, thin film silicon solar cells combine several advantageous aspects: firstly, thin-film silicon solar cells can be prepared by known thin-film deposition techniques such as plasma enhanced chemical vapor deposition (PECVD) and thus offer the perspective of synergies to reduce manufacturing cost by using experiences from display production technology. Secondly, thin-film silicon solar cells can achieve high energy conversion efficiencies striving towards 10% and beyond. Thirdly, the main raw materials for the production of thin-film silicon based solar cells are abundant and non-toxic.

### DEFINITIONS

Processing in the sense of this invention includes any chemical, physical or mechanical effect acting on substrates. Substrates in the sense of this invention are components, parts or workpieces to be treated in a processing apparatus. Substrates include but are not limited to flat, plate shaped parts having rectangular, square or circular shape. In a preferred embodiment this invention addresses essentially planar substrates of a size >1 m², such as thin glass plates.

A vacuum processing or vacuum treatment system or apparatus comprises at least an enclosure for substrates to be treated under pressures lower than ambient atmospheric pressure. CVD Chemical Vapour Deposition is a well known technology allowing the deposition of layers on heated substrates. A usually liquid or gaseous precursor material is being fed to a process system where a thermal reaction of said precursor results in deposition of said layer. LPCVD is a common term for low pressure CVD.

DEZ—diethyl zinc is a precursor material for the production of TCO layers in vacuum processing equipment. TCO stands for transparent conductive oxide, TCO layers consequently are transparent conductive layers.

The terms layer, coating, deposit and film are interchangeably used in this disclosure for a film deposited in vacuum processing equipment, be it CVD, LPCVD, plasma enhanced CVD (PECVD) or PVD (physical vapour deposition)

A solar cell or photovoltaic cell (PV cell) is an electrical compovent, capable of transforming light (essentially sun light) directly into electrical energy by means of the photoelectric effect. A thin-film solar cell in a generic sense includes, on a supporting substrate, at least one p-i-n junction established by a thin film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term thin-film indicates that the layers mentioned are being deposited as thin layers or films by processes like, PEVCD, CVD, PVD or alike. Thin layers essentially mean layers with a thickness of 10 μm or less, especially less than 2 μm.

### BACKGROUND OF THE INVENTION/RELATED ART

Amongst various approaches to prepare thin film silicon solar cells particularly the concept of amorphous-microcrystalline silicon multi-junction solar cells offer the perspective of achieving energy conversion efficiencies exceeding 10% due to the better use of the solar irradiation compared to, for example, an amorphous silicon single junction solar cell. In such a multi-junction solar cell 2 or more sub-cells can be stacked by depositing the corresponding layers subsequently. If materials of different band gap are used as absorber layers, the material with the largest band gap will be on the side of the device, which is oriented to the incident direction of the light. Such a solar cell structure offers several possible advantages: firstly, due to the use of 2 or more photovoltaic junctions of different band gap, the light with a broad spectral distribution as for example solar irradiation can be used more efficiently due to the reduction of thermalization losses. Secondly, due to the fact that high-quality microcrystalline silicon does not suffer from light induced degradation, as known for amorphous silicon due to the so-called Staebler-Wronski-effect, an amorphous-microcrystalline silicon multi-junction solar cell shows a smaller degradation of its initial conversion efficiency compared to an amorphous silicon single junction solar cell.

FIG. 1 shows a tandem-junction silicon thin film solar cell as known in the art. Such a thin-film solar cell 50 usually includes a first or front electrode 42, one or more semiconductor thin-film p-i-n junctions (52-54, 51, 44-46, 43), and a second or back electrode 47, which are successively stacked on a substrate 41. The direction of incident light is indicated by arrows on the figures. Each p-i-n junction 51, 43 or thin-film photoelectric conversion unit includes an i-type layer 53, 45 sandwiched between a p-type layer 52, 44 and an n-type layer 54, 46 (p-type =positively doped, n-type=negatively doped, i-type=substantially intrinsic). Substantially intrinsic in this context is understood as undoped or exhibiting essentially no resultant doping. Photoelectric conversion occurs primarily in this i-type layer; it is therefore also called absorber layer.

Depending on the crystalline fraction (crystallinity) of the i-type layer 53, 45 solar cells or photoelectric (conversion) devices are characterized as amorphous (a-Si, 53) or microcrystalline (μc-Si, 45) solar cells, independent of the kind of crystallinity of the adjacent p and n-layers. Microcrystalline layers are being understood, as common in the art, as layers comprising of a significant fraction of crystalline silicon—so called micro-crystallites—in an amorphous matrix. Stacks of p-i-n junctions are called tandem or triple junction photovoltaic cells. The combination of an amorphous and microcrystalline p-i-n- junction, as shown in FIG. 1, is also called micromorph tandem cell.

### DRAWBACKS KNOWN IN THE ART

For optimum conversion efficiency of an amorphous-microcrystalline multi-junction thin film solar cell, the solar cell needs to have both good Voc as well as a high current density Jsc, both at good fill factor FF. One important factor for achieving this is an efficient n-type layer 46 for the microcrystalline silicon bottom cell (43 in FIG. 1). This n-type layer has to fulfill 2 functions: First, it has to provide for a sufficient built-in electric field of the microcrystalline bottom cell, secondly it has to provide for an efficient low-resistive contact to the back contact applied. Furthermore, a second requirement is to have a low absorption particularly in the long wavelength part of the spectra, since light absorbed in this layer will not contribute to the generation of photocurrent, and thus, loss of light reflected from the back contact/back reflecfor will reduce the current density of the cell. The latter point becomes particularly relevant when preparing thin solar cell structures with a well elaborated light management, which is highly desirable with regard to the throughput of an industrial production line.

It was shown that highly crystalline microcrystalline silicon with a crystallinity measured e.g. by Raman scattering of greater than RC=60% can be easily doped and optimized to low resistivity and thus provide for a high built-in field in the cell as well as a low ohmic contact. However, due to its low band gap of 1.1 eV highly crystalline microcrystalline silicon exhibits a high absorption in the long wavelength part of the spectra, thus leading to a loss of light in the cell. In addition, highly crystalline microcrystalline silicon is usually prepared in a deposition regime using a very high hydrogen dilution ratio of the process gases, leading to a low deposition rate and therefore, long deposition time, which is detrimental to the throughput of a production system and therefore, for production cost.

Due to its larger band gap of around 1.7 eV, a thin amorphous silicon layer has a lower absorption in the low energy part of the spectra and can thus be beneficial regarding absorption loss. However, amorphous silicon has a far lower doping efficiency, thus leading to a lower amount of free carriers and therefore, a less efficient built-in field in the cell and a non-optimum contact behavior towards the back contact, thus requiring a larger doped layer thickness, which may possibly also lead to an enlarged degradation.

In order to address this problem, EP 1 650 812 A1 describes a double structured n-layer in which the first part consists of a highly oxidized n-layer and the second part consists of highly conductive microcrystalline silicon, which provides for the contact to the back contact layer of the cell. EP 1 650 812 proposes using the beneficial effect on the light trapping in the cell by the optical properties of the highly oxygen containing n-type layer, however they also state that the second contact layer is necessary to keep the conductivity of the n-layer acceptable, since the resistance of a highly-oxygen containing layer is very high. However, such a second contact layer also has a negative impact on the deposition time and therefore on the manufacturing cost of the thin film silicon solar cell device.

Similarly, US 2009/0133753 set out to improve the performance of solar cells by providing, in one embodiment, adjacent to the back electrode, a first layer consisting of n-type microcrystalline silicon, followed by a n-type Si₁₋ₓOₓ layer, followed by an i-type buffer layer mainly made of hydrogenated amorphous silicon, itself followed by the conventional i-type silicon layer. Such a complex structure equally has a negative impact on the deposition time and the manufacturing cost of the thin-film silicon solar cell device.

A further example is given by JP 4167473.

### SUMMARY OF THE INVENTION

The aim of the present invention is to remedy the above-mentioned drawbacks of the prior art. This is achieved by a light conversion device according to independent claim 1, comprising a front electrode and back electrode, and at least one photovoltaic light conversion layer stack situated between the front and back electrodes. This layer stack comprises a p-doped silicon layer, and essentially intrinsic silicon layer, and an n-doped layer, these layers together forming a p-i-n junction. The n-doped layer of the layer stack situated nearest to the back electrode, i.e. furthest from the front electrode and substrate, is situated in direct and intimate contact with the back electrode and essentially consists of a silicon- and oxygen-containing doped microcrystalline material, otherwise known as a n-doped microcrystalline SiOx layer. By microcrystalline layer, it is to be understood that this signifies a layer deposited under a process regime suitable for depositing a microcrystalline layer. This arrangement of layers with an n-doped SiOx layer being provided directly on the back electrode, i.e. directly adjacent thereto with-out any intermediate contact or adhesion layer(s), simplifies the structure and reduces production time and costs. The material is said as consisting essentially of silicon- and oxygen-containing microcrystalline material, as it additionally contains customarily, and as perfectly known to the skilled artisan, hydrogen, thus is more accurately addressed as SiOx:H.

In an embodiment, the n-doped layer is additionally situated in direct and intimate contact with the essentially intrinsic silicon layer, thus eliminating any intermediate layers between these two layers, simplifying the structure and reducing production time and costs. In addition, arranging the SiOx n-doped layer directly on the intrinsic layer creates a backside passivation effect on the intrinsic silicon layer, reducing the problems created by a highly uneven interface surface, and increasing the efficiency and longevity of the light conversion device.

In an embodiment, the oxygen content of the n-doped layer is chosen such that the refractive index n of the n-doped layer is at a wavelength of light of 500 nm is greater than or equal to 2.0. This enables the n-doped layer additionally to function as a reflector, thus increasing the efficiency of the light conversion device by causing more light to be reflected back into the absorber layer before reaching the back electrode, since this reflected light does not have to travel twice through the electrode layer and is in consequence not attenuated by this latter.

In an embodiment, the thickness of the n-doped layer is between 10-150 nm, preferably 20-50 nm, optimising the efficiency of manufacturing and of light conversion of the light conversion device.

Furthermore, a solar cell or a solar panel comprising a light conversion device of the above-mentioned type is foreseen.

Still further, the aim of the present invention is also achieved by a method for manufacturing a light conversion device according to independent claim 7. This method comprises providing a transparent substrate and a front electrode directly or indirectly thereupon.

Upon this front electrode is provided directly or indirectly at least one p-i-n junction of at least one photovoltaic light conversion layer stack. Each stack comprises a p-doped silicon layer, and essentially intrinsic silicon layer provided directly or indirectly upon the p-doped silicon layer, and an n-doped layer provided directly or indirectly on the intrinsic silicon layer. A back electrode is finally provided on the n-doped layer. The back electrode is provided directly on the n-doped layer situated furthest from the substrate, which in the case of a single layer stack would be the only n-doped layer, and this n-doped layer consists of a silicon- and oxygen-containing doped microcrystalline layer, that is to say that the layer is deposited under a process regime suitable for depositing a microcrystalline layer. This eliminates the requirement for any intermediate adhesion or interface layers, thus simplifying production and reducing production time and costs.

In an embodiment, the n-doped layer is provided directly on the essentially intrinsic silicon layer. This simplifies the structure and reduces production time and costs. In addition, arranging the SiOx n-doped layer directly on the intrinsic layer has a backside passivation effect on the intrinsic silicon layer, reducing the problems created by a highly uneven interface surface, and increasing the efficiency and longevity of the light conversion device.

In an embodiment, the oxygen content of the n-doped layer is chosen such that the refractive index n of the n-doped layer at a wavelength of light of 500 nm is greater than or equal to 2.0. This enables the n-doped layer additionally to function as a reflector, thus increasing the efficiency of the light conversion device by causing more light to be reflected back into the absorber layer before reaching the back electrode, since this reflected light does not have to travel twice through the electrode layer and is not attenuated by this latter.

In an embodiment, the method is carried out by means of Plasma Enhanced Chemical Vapour Deposition PECVD in a corresponding PECVD reactor. This enables efficient production of good-quality layers.

In an embodiment, the n-doped layer is applied on the intrinsic layer by applying a controlled backside passivation by plasma treatment. Using this treatment to apply the n-doped layer ensures that the passivation effect of the SiOx layer is maximised.

In an embodiment, the n-doped layer is created by establishing in the PECVD plasma reactor a first plasma deposition regime. In this regime an overall process gas flow of substantially 0.3-1 sccm/cm² of substrate size to be treated is established, the process gas comprising silane (SiH₄), hydrogen (H₂), and a n-doped gas. This n-doped gas can be phosphine (PH₃) diluted to a concentration of 0.5% in hydrogen. The ratio of silane to n-doped gas is between 1:1 and 1:5, and the ratio of silane to hydrogen is between 1:50 and 1:200, preferably 1:100. The process pressure is chosen between 1.5 and 8 mbar, preferably 2.5-5 mbar, with an RF power of 150-200 mW/cm², preferably 170-180 mW/cm² at a frequency of 13.56-60 MHz, preferably 40 MHz, is generated in the reaction chamber of the PECVD plasma reactor. This first plasma regime is maintained for a time of 10-20 seconds, and then, leaving all the other process parameters the same, a flow of oxygen-comprising gas, preferably carbon dioxide, is additionally introduced into the reaction chamber. The flow ratio between silane and oxygen-containing gas is between 2:1 and 1:3, preferably between 1:1 and 1:2. These process parameters enable the deposition of an SiOx layer having highly desirable properties for the application, including adequate conductivity and a good backside passivation effect on the underlying silicon layer.

### BRIEF DESCRIPTION OF THE DRAWINGS

FIG. 1 shows a prior-art tandem junction thin-film silicon photovoltaic cell (not to scale); and

FIG. 2 shows a thin-film silicon photovoltaic cell according to an embodiment of the invention, incorporating a microcrystalline n-SiOx layer in the bottom cell (not to scale).

### DETAILED DESCRIPTION OF THE INVENTION

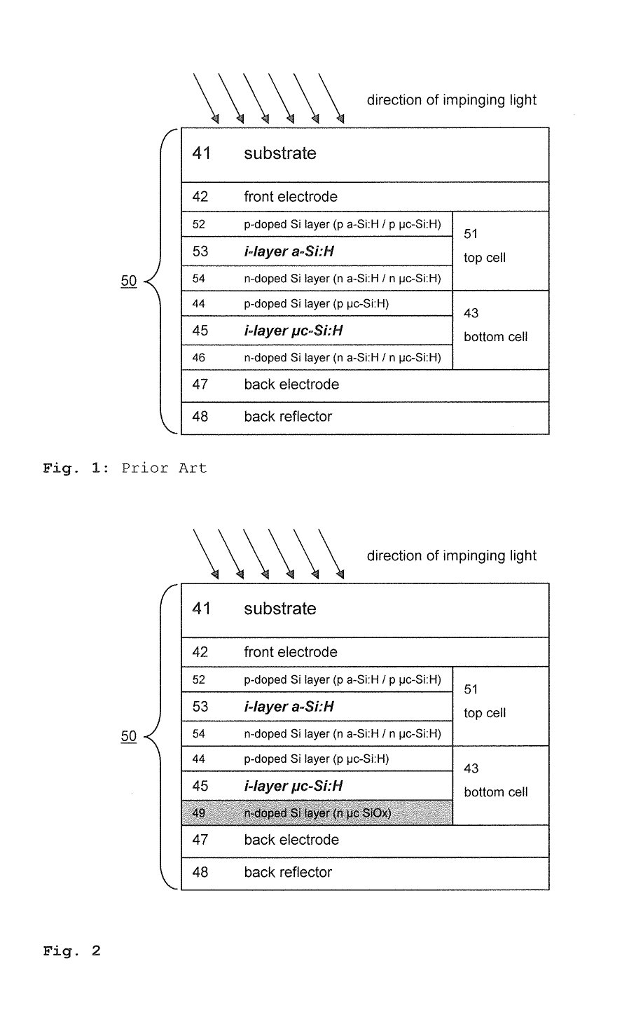

It was found that both requirements for the n-layer such as high transmission in the long wavelength part of the spectra as well as a contribution to back reflection of light into the absorber layer before reaching the back contact in combination with sufficiently good electrical behavior can be achieved even without a second contact layer. It could be shown that it is possible to obtain this by applying a single SiOx n-type layer 49 (FIG. 2) in place of the conventional n-doped silicon layer 46 of prior art (FIG. 1), when the properties of such a layer are optimized in an appropriate range in combination with an appropriate n-layer/back contact interface. The optimization can be realized by
a) Choosing the oxygen content of such an inventive SiOx layer in a range that the refractive index n at a wavelength of the light of 500 nm is in not smaller than 2.0.
b) Increasing the doping of said inventive SiOx layer by a sufficiently high dopant gas flow to achieve a reasonable conductivity.
c) Applying a controlled back side passivation by a plasma treatment as described in WO 2010/012674 A2 (incorporated herewith by reference in its entirety).

Accordingly the above-mentioned SiOx n-layer 49 is achieved by establishing, in a PECVD plasma reactor, a first plasma deposition regime with an overall gas flow of essentially 0.3-1 sccm/cm² of substrate size to be treated. The process gas comprises silane, hydrogen and a n-dopant gas (e.g. Phosphine diluted to a concentration of 0.5% in hydrogen). The ratio of silane vs. dopant gas is held between 1:1 to 1:5. The ratio between silane and hydrogen shall be established between 1:50 and 1:200, preferably 1:100. The overall process pressure is chosen in the range between 1.5 and 8 mbar, preferably 2.5-5 mbar while a RF power of 150-200 mW/cm², preferably 170-180 mw/cm² is established (13.56-60 MHz, preferably 40 MHz). This first plasma regime shall be held for a time span of 10-20 s, after which a second plasma regime is initiated which is, regarding power density, silane, Phosphine, hydrogen ratios the same. Additionally a flow of oxygen comprising gas such as carbon dioxide is established. The flow ratio between silane and oxygen-containing gas shall be between 2:1 to 1:3, preferably between 1:1 and 1:2. An overall n-layer thickness between 10-150 nm is sufficient, preferably 20-50 nm for economic reasons.

In the setup of the plasma discharge reactor of an Oerlikon Solar KAI 1200 plasma deposition system, such a layer may be deposited by choosing the following deposition conditions: First, in a deposition reactor capable of processing 1.4 m² substrates a plasma discharge is ignited. The process gas composition per reactor is defined by a silane flow F(SiH₄)=80 sccm, a hydrogen flow of F(H₂)=7800 sccm, a dopant gas flow of Phosphine (diluted in hydrogen at a concentration of 0.5%) of F(PH₃/H₂)=400 sccm. The process pressure is set to 2.5 mbar at a plasma discharge power of 2500 W.

After a short plasma stabilization step of 15 s a carbon dioxide gas flow of F(CO₂)=120 sccm is added as oxygen source gas, while the other process parameters remain unchanged. Under these conditions, the desired n-type layer will be prepared in 220 s, leading to a layer thickness of approximately 40 nm at a deposition rate of 1.8 A/s.

In an experiment, it could be shown that by applying such type of n-layer, the solar cell characteristics could be improved as follows:

Samples using such type of n-layer: ΔVoc=+0.02%, ΔFF=−0.06%, ΔJsc=+2.2%, Δ(ρ)=+2.2%.

Although the invention has been described in terms of specific embodiments, the invention is not be construed as limited to such, but comprises all embodiments which fall within the scope of the appended claims. For instance, both the n-, i- and p-doped silicon layers can be either microcrystalline hydrogenated silicon (μc Si:H), or amorphous microcrystalline hydrogenated silicon (a-Si:H), and there can be any number of cells constituting the light conversion device.

### LIST OF REFERENCE SIGNS

41—Substrate
42—Front electrode
43—Bottom cell
44—p-doped Si layer (p pc-Si:H)
45—i-layer pc-Si:H
46—n-doped Si layer (n a-Si:H/n μc-Si:H)
47—Back electrode
48—Back reflector
49—n-doped Si layer (n μc-SiOx)
50—Thin-film solar cell
51—Top cell
52—p-doped Si layer (p a-Si:H/p μc-Si:H)
53—i-layer a-Si:H
54—n-doped Si layer (n a-Si:H/n μc-Si:H)

1. Light conversion device comprising a front electrode and a back electrode, and at least one photovoltaic light conversion layer stack situated between said front and back electrodes, said layer stack comprising a p-doped silicon layer, an essentially intrinsic silicon layer, and an n-doped layer, said layers together forming a p-i-n junction, characterised in that the n-doped layer nearest to the back electrode is situated in direct and intimate contact with said back electrode and essentially consists of a silicon- and oxygen-containing doped microcrystalline material.

2. Light conversion device according to claim 1, wherein the said n-doped layer is further situated in direct and intimate contact with the essentially intrinsic silicon layer.

3. Light conversion device according to claim 2, wherein the n-doped layer is arranged so as to cause back side passivation of the adjacent intrinsic silicon layer.

4. Light conversion device according to claim 1, wherein the oxygen content of the n-doped layer is chosen such that the refractive index n of the n-doped layer at a wavelength of light of 500 nm is greater than or equal to 2.0.

5. Light conversion device according to claim 1, wherein the thickness of the n-doped layer is between 10-150 nm, preferably 20-50 nm.

6. Solar cell or solar panel comprising a light conversion device according to claim 1.

7. Method for manufacturing a light conversion device comprising the steps of:
a) providing a transparent substrate;
b) providing a front electrode directly or indirectly on said substrate;
c) providing directly or indirectly on said front electrode at least one p-i-n junction of at least one photovoltaic light conversion layer stack, each conversion layer stack comprising a p-doped silicon layer, an essentially intrinsic silicon layer provided directly or indirectly on said p-doped silicon layer, and an n-doped layer provided directly or indirectly on said essentially intrinsic silicon layer,
d) providing a back electrode on the said n-doped layer situated furthest from the substrate,
characterised in that the back electrode is provided directly on the n-doped layer situated furthest from the substrate, and in that this n-doped layer consists essentially of a silicon- and oxygen-containing doped microcrystalline material.

8. Method according to claim 7, wherein the said n-doped layer is provided directly on the adjacent essentially intrinsic silicon layer.

9. Method according to claim 7, wherein the oxygen content of the said n-doped layer is chosen such that the refractive index n of the said n-doped layer at a wavelength of light of 500 nm is greater than or equal to 2.0.

10. Method according to claim 7, wherein the method is carried out by means of Plasma Enhanced Chemical Vapor Deposition PECVD in a corresponding PECVD plasma reactor.

11. Method according claim 10, wherein the said n-doped layer is applied on the intrinsic layer by applying a controlled backside passivation by plasma treatment.

12. Method according to claim 10, wherein the said n-doped layer is created by establishing in said PECVD plasma reactor a first plasma deposition regime with an overall process gas flow of substantially 0.3-1 sccm/cm² of substrate size to be treated, said process gas comprising silane, hydrogen and an n-dopant gas, said n-dopant gas preferably being 0.5% phosphine in hydrogen, the ratio of silane to n-dopant gas being between 1:1 and 1:5, and the ratio of silane to hydrogen being between 1:50 and 1:200, preferably 1:100.

13. Method according to claim 12, wherein the process pressure is chosen between 1.5 and 8 mbar, preferably 2.5-5 mbar, and an RF power of 150-200 mW/cm², preferably 170-180 mW/cm² at a frequency of 13.56-60 MHz, preferably 40 MHz, is established in the PECVD reactor.

14. Method according to claim 12, wherein said first plasma regime is maintained for a time of 10-20 s, after which a flow of oxygen-comprising gas, preferably carbon dioxide, is additionally introduced, all other process parameters remaining the same, and whereby the flow ratio between silane and oxygen-containing gas is between 2:1 and 1:3, preferably between 1:1 and 1:2.
